(19) United States
(12) Patent Application Publication
(10) Pub. No.: US 2007/0285962 A1
(43) Pub. Date: Dec. 13, 2007

(54) PHASE CHANGE MEMORY DEVICE AND FABRICATION METHOD THEREOF

(75) Inventors: Chuo Yen, Taipei City (TW); Ming-Hau Tseng, Taoyuan County (TW)

Correspondence Address: QUINTERO LAW OFFICE, PC, 2210 MAIN STREET, SUITE 200, SANTA MONICA, CA, 90405, US

(73) Assignees: INDUSTRIAL TECHNOLOGY RESEARCH INSTITUTE, HSINCHU (TW); POWERCHIP SEMICONDUCTOR CORP., HSIN-CHU (TW); NANYA TECHNOLOGY CORPORATION, TAOYUAN (TW); PROMOS TECHNOLOGIES INC., HSINCHU (TW); WINBOND ELECTRONICS CORP., HSINCHU (TW)

(21) Appl. No.: 11/741,717

(22) Filed: Apr. 27, 2007

(30) Foreign Application Priority Data
May 23, 2006 (TW) TW95118259

(51) Int. Cl. G11C 11/00; H01L 21/76

(52) U.S. Cl. 365/129; 438/400; 257/E21.602

(57) ABSTRACT

A phase change memory device is disclosed. A first columnar electrode and a second columnar electrode are provided, both arranged horizontally. A phase change layer is interposed between the first columnar electrode and the second columnar electrode, electrically connecting both thereof, wherein the entirety of the phase change layer is disposed on a plane. A bottom electrode electrically connects the first columnar electrode. A top electrode electrically connects the second columnar electrode.

### BACKGROUND OF THE INVENTION

1. Field of the Invention

The present invention relates to memory devices, and in particular to a phase change memory device and fabrication thereof.

2. Description of the Related Art

Phase change memory devices have many advantages, such as high speed, low power consumption, large capacity, endurance, improved process integrity, and lower cost, with resulting suitability for use as independent or embedded memory devices with high integrity. Phase change memory devices can efficiently replace volatile memory devices, such as SRAM and DRAM, or non-volatile memory devices, such as flash memory devices.

FIG. 1A shows a conventional T shaped phase change memory device. Referring to FIG. 1A, a conventional T-shaped phase change memory device sequentially comprises a bottom electrode 102, a bottom via 104, a phase change layer 106, a top via 108 and a top electrode 110, wherein the columnar bottom via 104 is a heating electrode, connecting the phase change layer 106. Contact area of the bottom via 104 and the phase change layer 106 is determined by size of the bottom via 104. The size of the bottom via 104, however, is determined according to the limits of photolithography, rendering reduction of dimensions difficult.

FIG. 1B shows another conventional phase change memory device, in which a heating electrode 112 is disposed horizontally. Contact area of the heating electrode 112 and a phase change materials layer 114 is determined according to thickness of the heating electrode 112, and is thus not subject to process limits of photolithography. Phase change materials layer 114 of the phase change memory device, however, is formed by gap filling, negatively affecting endurance and uniformity of contact between the phase change materials layer 114 and the heating electrode 112 of the phase change memory device are not good enough. In addition, the heating electrode 112 must comprise highly resistant materials to increase heating efficiency. Due to longer current path of the heating electrode 112 and the phase change material layer 114, the phase change memory device consumes more power. Further, the horizontal phase change material layer 114 requires more lithography steps than conventional T-shaped phase change memory devices, increasing costs.

As shown in FIG. IC, U.S. Pat. No. 6,867,425 discloses a lateral phase change memory device. A conductive material is formed on a substrate 150 and then patterned to form two electrodes 152 and 153, supplying current to a phase change material layer 154. A dielectric layer 156 is interposed between the phase change material layer 154 and the electrode 152 and 153, and a protective layer 158 comprising dielectric materials covers the phase change material layer 154. However, the phase change material layer 154 of the phase change memory device is still formed by gap filling, with accompanying deterioration of endurance and uniformity of contact between the phase change material layer 154 and the heating electrodes 152 and 153. In addition, filling phase change materials into the gap between the electrodes 152 and 153 becomes more difficult with the reduced distance therebetween. Further, current path in the heating electrode, comprising highly resistant materials to achieve good heating efficiency, is longer than that of the conventional phase change memory device, consuming more power. In addition to the heating electrode, two additional conducing electrodes 152 and 153 are required on both sides of the phase change material layer 154, increasing area occupied. The lateral phase change memory device, finally, still requires more photolithography steps than conventional T-shaped phase change memory devices, with correspondingly increased cost.

### BRIEF SUMMARY OF INVENTION

A detailed description is given in the following embodiments with reference to the accompanying drawings. According the issues above, Example of the present invention may provide a phase change memory device with shorter current path and fewer defects than conventional phase change memory device with a phase change layer formed in a trench. In addition, example of the present invention may provide a phase change memory device, in which area of a contacting region between a phase change layer and an electrode is determined by a thickness of the phase change layer, such that not limited to photolithography.

In an embodiment of the invention, a phase change memory device comprises a first columnar electrode and a second columnar electrode, both arranged horizontally. A phase change layer is interposed between the first columnar electrode and the second columnar electrode, electrically connecting both thereof, wherein the entirety of the phase change layer is disposed on a plane. A bottom electrode electrically connects the first columnar electrode. A top electrode electrically connects the second columnar electrode.

The invention further provides a method for forming a phase change memory device. A substrate comprising a source and a drain is provided. A plurality of interconnects and vias are formed with at least one of the interconnects and vias electrically connecting to the drain. A bottom electrode and a first dielectric layer are formed overlying the interconnects or the vias, wherein the bottom electrode is disposed in the first dielectric layer. Lower portions of a first columnar electrode and a second columnar electrode and a second dielectric layer are formed overlying the bottom electrode and the first dielectric layer, wherein the lower portions of the first columnar electrode and the second columnar electrode are disposed in the second dielectric layer, and the lower portion of the first columnar electrode electrically connects to the bottom electrode. A patterned phase change layer is formed overlying portions of the lower portions of the first columnar electrode and the second columnar electrode, and the second dielectric layer. Upper portions of the first columnar electrode and the second columnar electrode, and a third dielectric layer are formed overlying the lower portions of the first columnar electrode and the second columnar electrode, and a portion of the patterned phase change layer to form entireties of the first columnar electrode and the second columnar electrode, wherein the patterned phase change layer extends into the first columnar electrode and the second columnar electrode. A top electrode is formed to electrically connect a portion of the second columnar electrode.

The invention provides another method for forming a phase change memory device. A substrate comprising a source and a drain is provided. A plurality of interconnects and vias are formed with at least one of the interconnects and vias electrically connecting the drain. A bottom electrode and a first dielectric layer are formed overlying the interconnects or the vias, wherein the bottom electrode is disposed in the first dielectric layer. A second dielectric layer is formed overlying the bottom electrode and the first dielectric layer. A phase change layer is formed overlying the second dielectric layer. A third dielectric layer is formed overlying the phase change layer and the second dielectric layer. A patterned photoresist layer is formed overlying the third dielectric layer. The second dielectric layer and the third dielectric layer are etched using the patterned photoresist layer as a mask to form at least two openings, wherein the openings penetrate portions of the phase change layer. A conductive material is filled into the openings to form at least two columnar electrodes.

### BRIEF DESCRIPTION OF DRAWINGS

The invention can be more fully understood by reading the subsequent detailed description and examples with references made to the accompanying drawings, wherein:

FIG. 1A shows a conventional T-shaped phase change memory device.

FIG. 1B shows another conventional phase change memory device.

FIG. 1C shows yet another phase change memory device.

FIG. 2A˜FIG. 2E are intermediate cross sections of fabrications of a phase change memory device of an embodiment of the invention.

FIG. 3 is a plan view of a phase change memory device of an embodiment of the invention.

FIG. 4A˜FIG. 4E are intermediate cross sections of fabrications of a phase change memory device of another embodiment of the invention.

FIG. 5A˜FIG. 5E are intermediate cross sections of fabrications of a phase change memory device of further another embodiment of the invention.

FIG. 6 is a plan view of a phase change memory device of this embodiment.

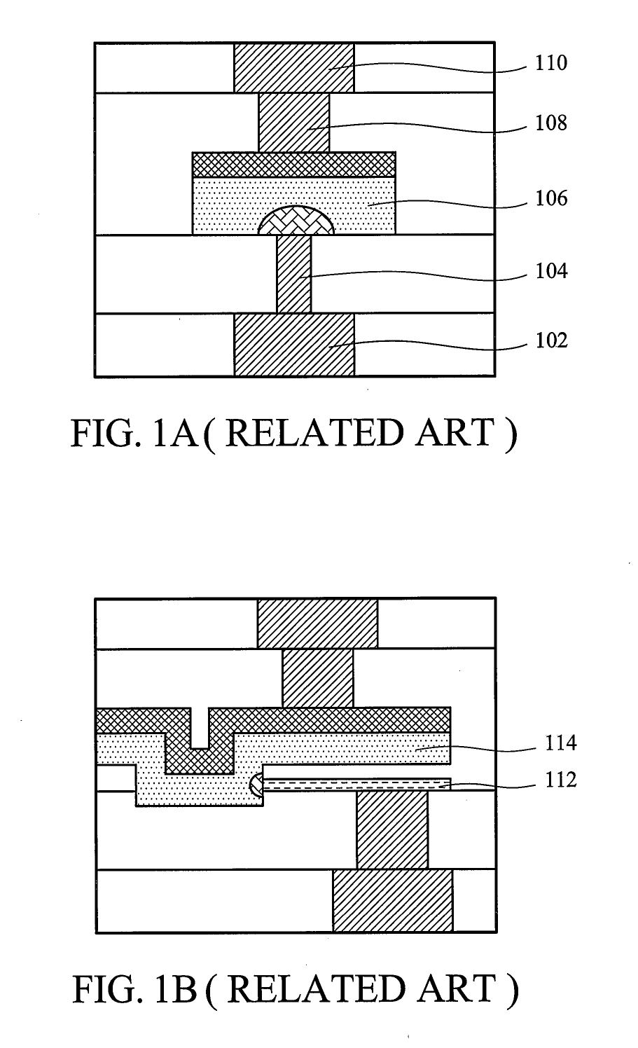

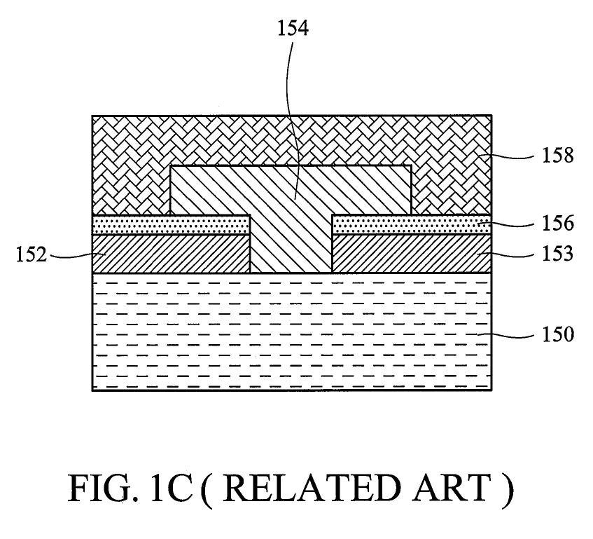

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims. Embodiments of the invention, which provides a phase change memory device, will be described in greater detail by referring to the drawings that accompany the invention. It is noted that in the accompanying drawings, like and/or corresponding elements are referred to by like reference numerals.

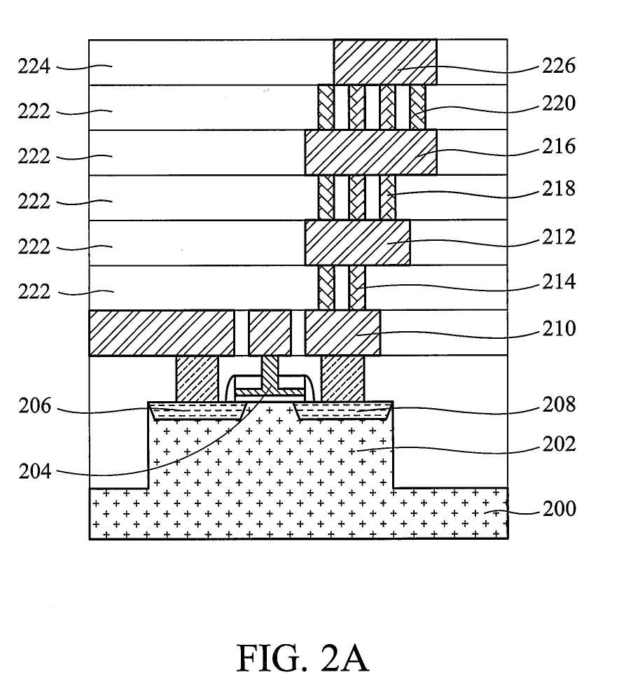

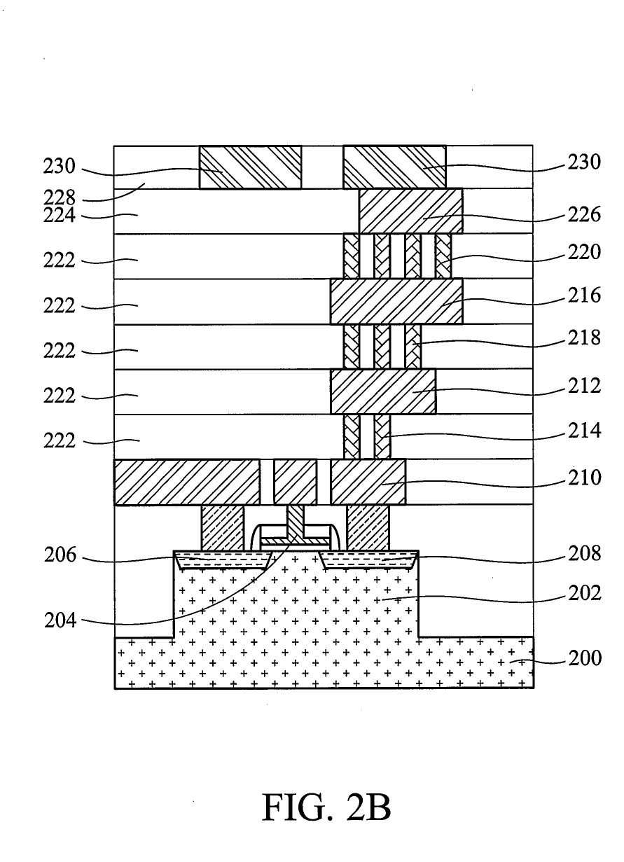

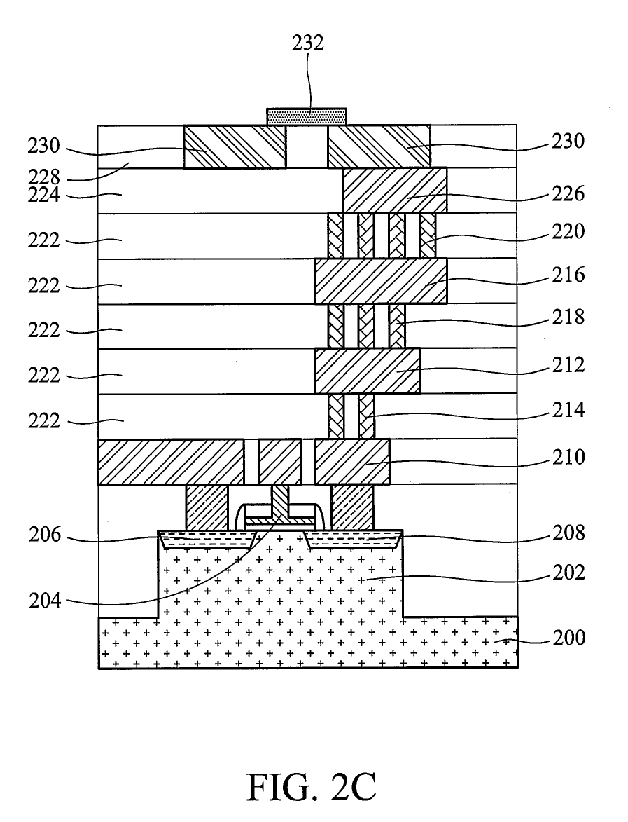

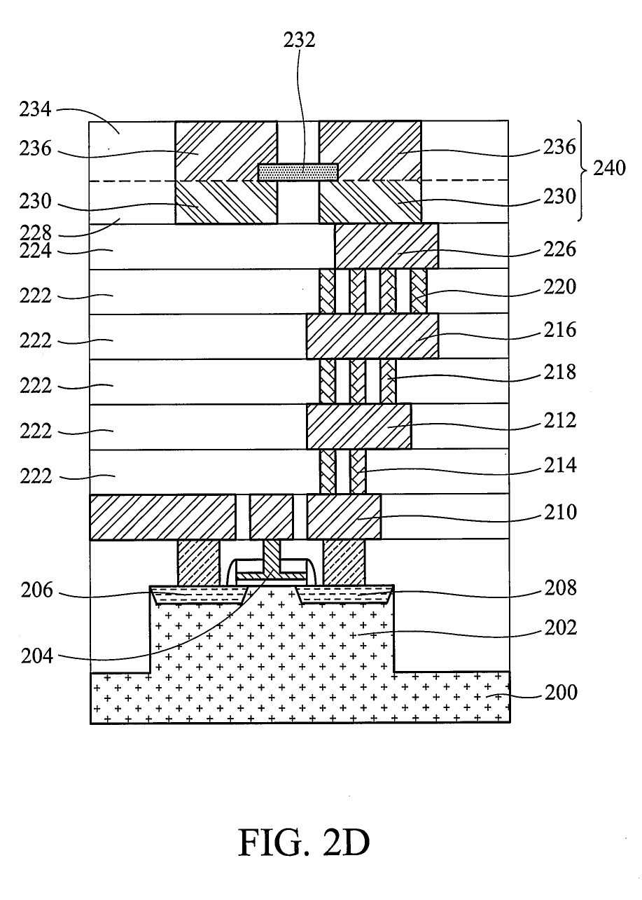

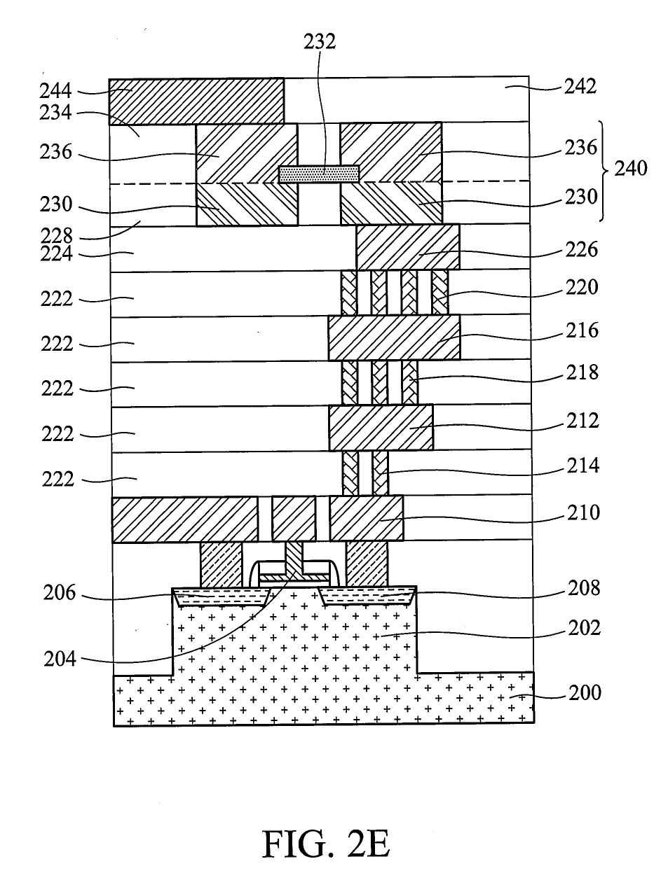

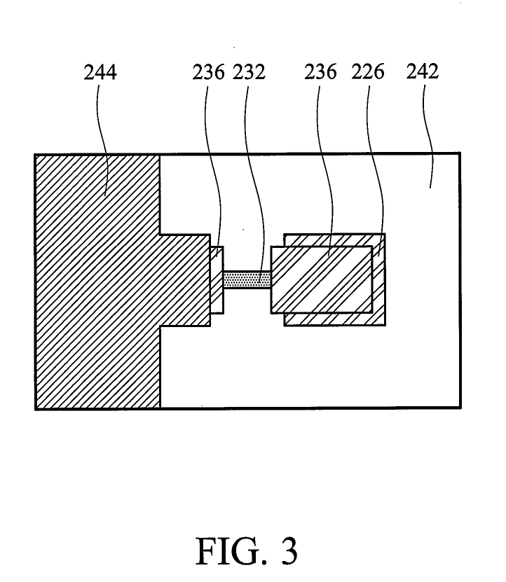

FIG. 2A˜FIG. 2E show intermediate cross sections of fabrications of a phase change memory device of an embodiment of the invention. Referring to FIG. 2A, a substrate 200 comprising an active 202 is provided, wherein a gate 204 is formed on the active area 202. Source 206 and drain 208, which both are doped regions, are formed on opposite sides of the gate 204. The gate 204, source 206 and drain 208 respectively connects a first interconnect 210. A second interconnect 212 is connected to the first interconnect 210 through first vias 214. A third interconnect 216 is connected to the second interconnect 212 through second vias 218. A plurality of third vias 220 is formed on the third interconnect 216. The vias 214, 218 and 220 are disposed in interlayer dielectric layers 222 separating the interconnects 210, 212 and 216.

A first dielectric layer 224, comprising silicon nitride, silicon oxide, or silicon oxynitride, is formed on the third vias 220. Next, the first dielectric layer 224 is patterned by a first photolithography step with a first mask to form an opening, and the opening is filled with conductive materials, such as TiN, Tan or TiW, to form a bottom electrode 226.

Referring to FIG. 2B, a second dielectric layer 228, such as silicon nitride, silicon oxide or silicon oxynitride, is formed on the first dielectric layer 224 and the bottom electrode 226. Next, the second dielectric layer 228 is patterned by a second photolithography step with a second mask to form at least two openings. Thereafter, refractory metals, such as W or TiAlN, metals with low heat conducting coefficient, phase change materials or chalcogenide are filled into the openings to form lower portions of columnar electrodes 230.

Referring to FIG. 2C, a phase change layer (not shown), comprising Ag, In, Te, Sb, Ge or combinations thereof, is blanketly deposited on the lower portions of the columnar electrodes 230 and the second dielectric layer 228. The phase change layer can be ternary chalcogenide compound, such as GeTe—Sb₂Te₃, or binary chalcogenide compound, such as combinations of Sb and Te in various percentages. The chalcogenide compound can comprise Cr, Fe, Ni, or combinations thereof, or Bi, Pb, Sn, As, S, Si, P, O, or combinations thereof.

Next, the phase change layer is patterned by a photolithography step with a third mask to form a patterned phase change layer 232, bridging the lower portions of the columnar electrodes 230.

Referring to FIG. 2D, a third dielectric layer 234, such as silicon nitride, silicon oxide or silicon oxynitride, is formed on the patterned phase change layer 232, second dielectric layer 228 and the lower portions of the columnar electrodes 230. Next, the third dielectric layer 234 is patterned by photolithography using the second mask, the same mask used when forming the lower portions of the columnar electrodes 230, to form at least two openings, each respectively exposing the corresponding lower portion of the columnar electrode 230. Note that the patterned phase change layer 232 is substantially unaffected during the etching step. Etching ratio between the third dielectric layer 234 and the patterned phase change layer 232 is substantially more than 10. Further note that deviations between positions of the openings and the corresponding lower portions of the columnar electrodes 230 cannot be too large.

Next, refractory metals, such as W or TiAlN, metals with low heat conducting coefficient, phase change materials or chalcogenide, are filled into the openings to form upper portions of the columnar electrodes 236, wherein the lower portions of the columnar electrodes 230 and the upper portions of the columnar electrodes 236 constitute columnar electrodes 240. The two columnar electrodes 240 are located on the same layer, and the patterned phase change layer 232 extends into both the columnar electrodes 240.

Referring to FIG. 2E, a fourth dielectric layer 242, of silicon nitride, silicon oxide, or silicon oxynitride, is formed on the columnar electrodes 240. Next, the fourth dielectric layer 242 is patterned by photolithography using a fourth mask to form an opening. A conductive material, such as TiN, TaN or TiW, is deposited into the opening, and then etched back to form a top electrode 244. Thus, a major portion of the phase change memory device is fabricated. Note that fabrications of the phase change memory of the embodiment may use only four photolithography mask and process steps, one step and mask less than that of conventional planar phase change memory device.

FIG. 3 is a plan view of a phase change memory device of an embodiment of the invention. Referring to FIG. 2E and FIG. 3, the patterned phase change layer 232 is formed on a plane, such that the entirety of the pattern phase change layer 232 is planar, having short current path and fewer defects than conventional phase change memory devices. In addition, area of the contact region of the electrode 240 and the patterned phase change layer 232 can be determined by thickness of the patterned phase change layer 232, not being limited by photolithography technology.

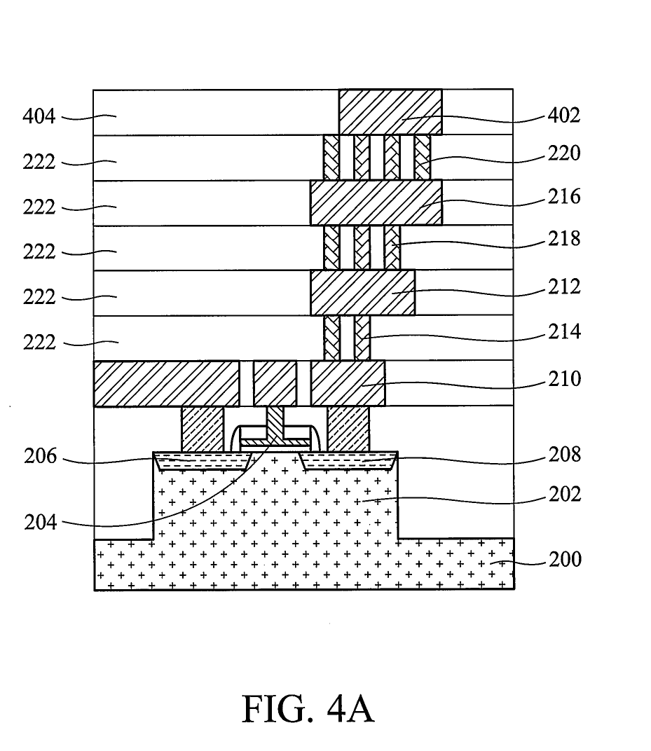

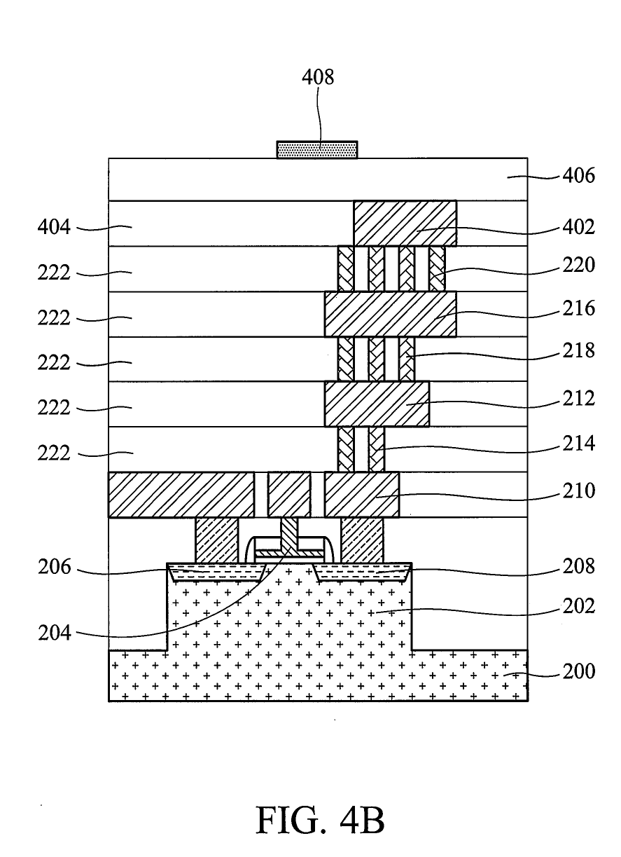

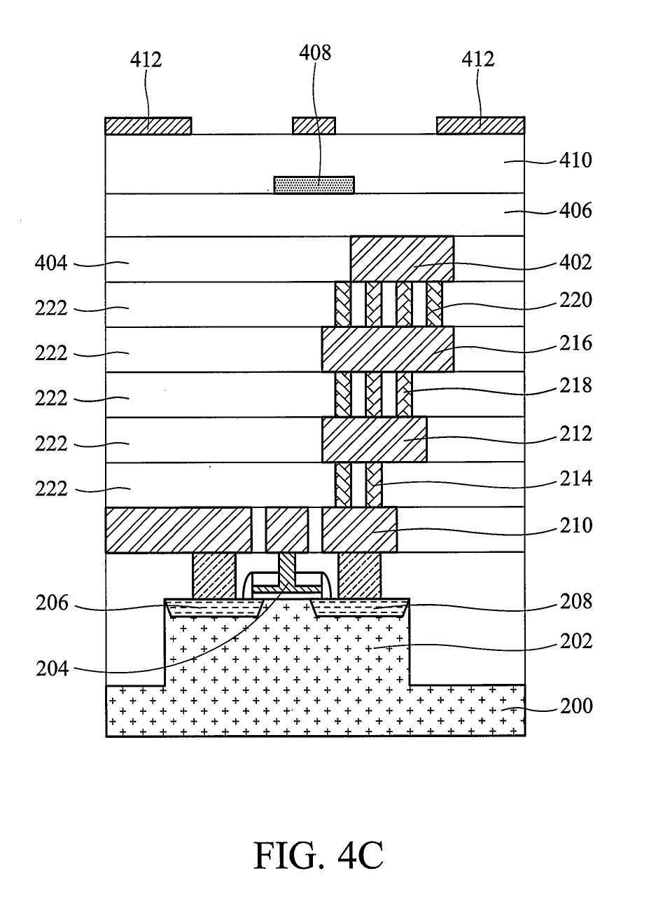

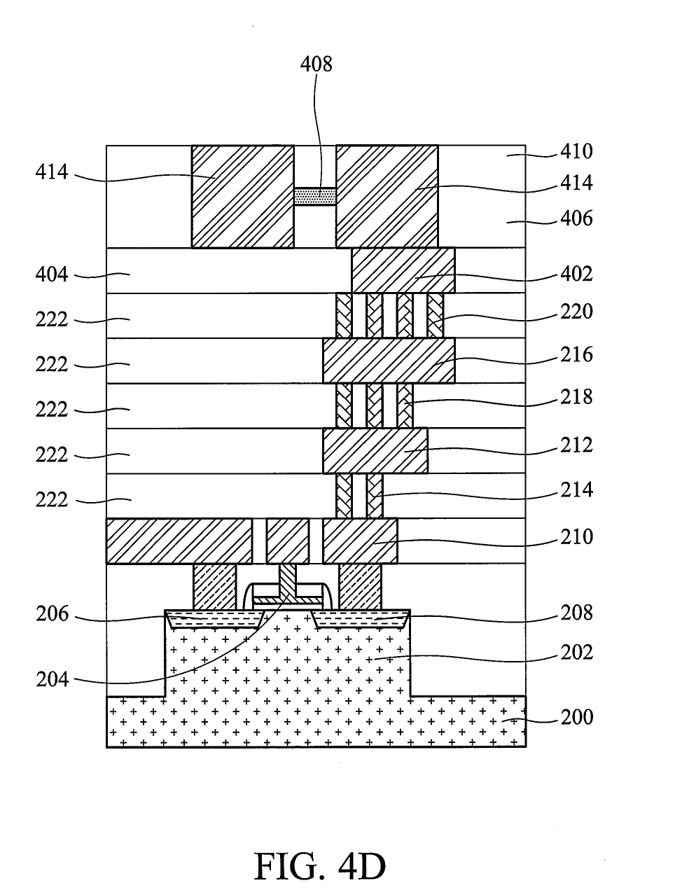

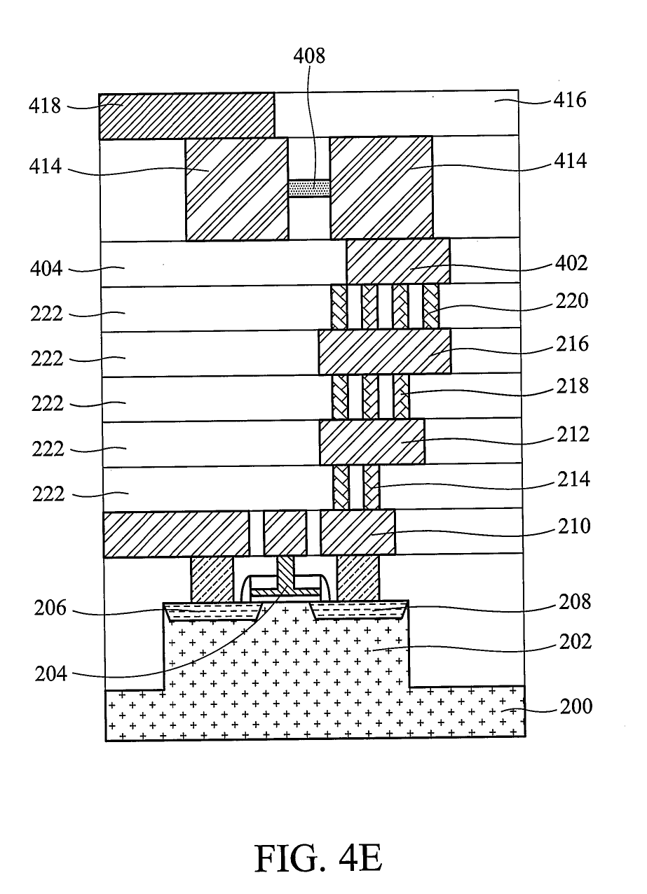

FIG. 4A˜FIG. 4E are intermediate cross sections of fabrications of a phase change memory device of another embodiment of the invention, wherein portions of the structure of the device under the bottom electrode are similar to the device of FIG. 2A˜FIG. 2E. Elements of this portion use the same symbol numbers as the device of FIG. 2A˜FIG. 2E. Referring to FIG. 4A, a substrate 200 comprising an active area 202 is provided, wherein a gate 204 is formed on the active area 202. Source 206 and drain 208, both doped regions, are formed on opposite sides of the gate 204. The gate 204, source 206 and drain 208 respectively connect to a first interconnect 210. A second interconnect. 212 is connected to the first interconnect 210 through first vias 214. A third interconnect 216 is connected to the second interconnect 212 through second vias 218. A plurality of third vias 220 is formed on the third interconnect 216. The vias 214, 218 and 220 are disposed in interlayer dielectric layers 222 separating the interconnects 210, 212 and 216.

A first dielectric layer 404, comprising silicon nitride, silicon oxide and silicon oxynitride, is formed on the third vias 220. Next, the first dielectric layer 404 is patterned by a first photolithography step with a first mask to form an opening. Conductive materials, such as TiN, TaN or TiW, are deposited into the opening to form a bottom electrode 402.

Referring to FIG. 4B, a second dielectric layer 406, such as silicon nitride, silicon oxide or silicon oxynitride, is formed on the first dielectric layer 404 and the bottom electrode 402. Next, a phase change layer (not shown), comprising Ag, In, Te, Sb, Ge or combinations thereof, is blanketly deposited on the second dielectric layer 406. The phase change layer can be ternary chalcogenide compound, such as GeTe—Sb₂Te₃, or binary chalcogenide compound, such as combination of Sb and Te in various percentages. The chalcogenide compound can comprise Cr, Fe, Ni or combinations thereof, or Bi, Pb, Sn, As, S. Si, P, O or combinations thereof. Thereafter, the phase change layer is patterned to by photolithography using a second mask to form a patterned phase change layer 408.

Referring to FIG. 4C, a third dielectric layer 410, such as silicon nitride, silicon oxide or silicon oxynitride, is formed on the patterned phase change layer 408 and the second dielectric layer 406. Next, a photoresist layer 412 is coated on the third dielectric layer 410, and then defined by exposure with a third mask.

Referring to FIG. 4D, the second dielectric layer 406 and the third dielectric layer 410 are etched using the defined photoresist layer 412 as a mask to form at least two openings, each penetrating a portion of the patterned phase change layer 408 at one side, in which the top electrode 402 or the first dielectric layer 404 are exposed. Next, refractory metals, such as W or TiAlN, metals with low heat conducting coefficient, phase change materials or chalcogenide, are filled into the openings to form two columnar electrodes 414. The two columnar electrodes 414 are on the same level, and the patterned phase change layer 408 contacts sidewalls of the columnar electrodes 414.

Referring to FIG. 4E, a fourth dielectric layer 416, such as silicon nitride, silicon oxide or silicon oxynitride, is formed on the columnar electrodes 414. Next, the fourth dielectric layer 416 is patterned by photolithography using a fourth mask to form an opening. A conductive material, such as TiN, TaN or TiW, is deposited into the opening, and then etched back to form a top electrode 418. Note that fabrication of the phase change memory of the embodiment may use only four masks and three photolithography steps, one mask and two photolithography steps less than a conventional planar phase change memory device.

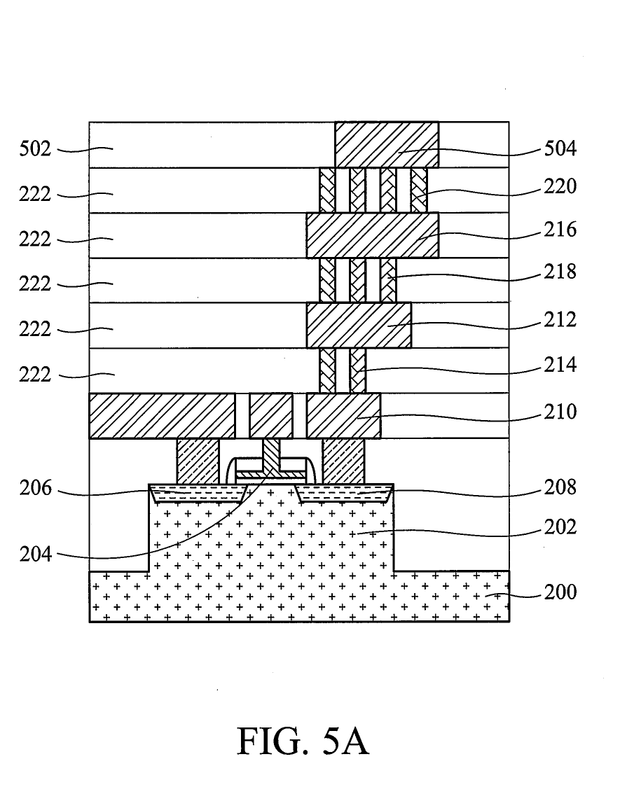

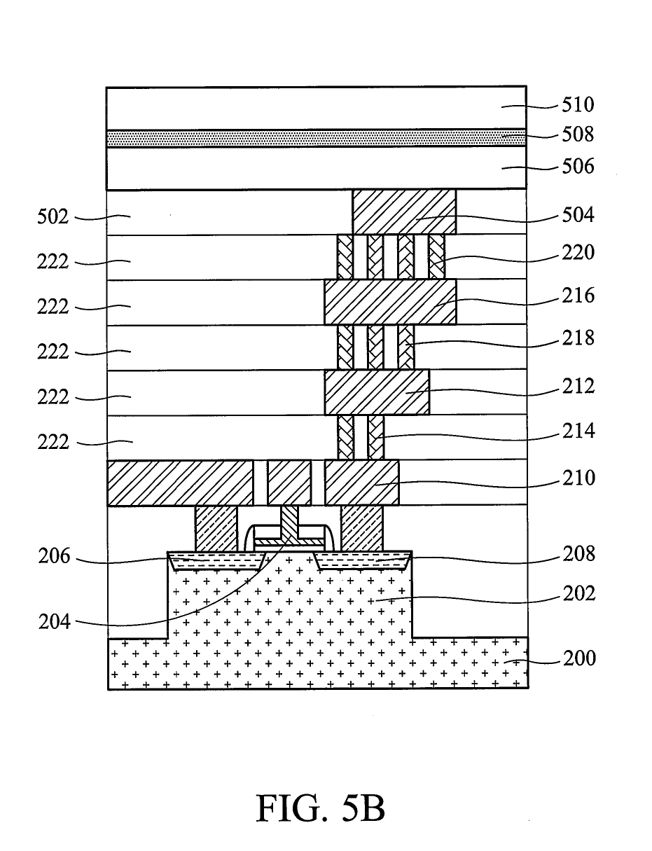

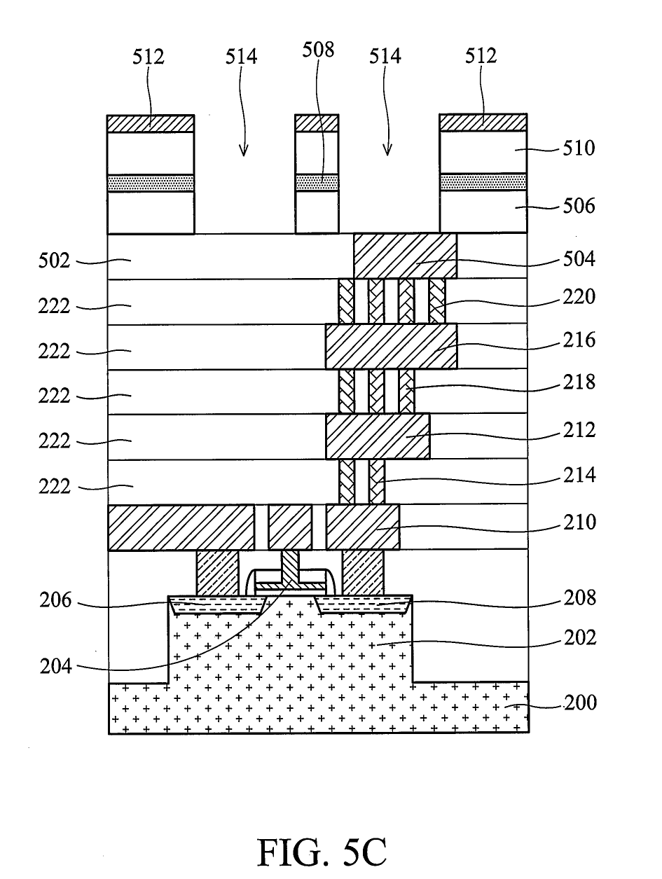

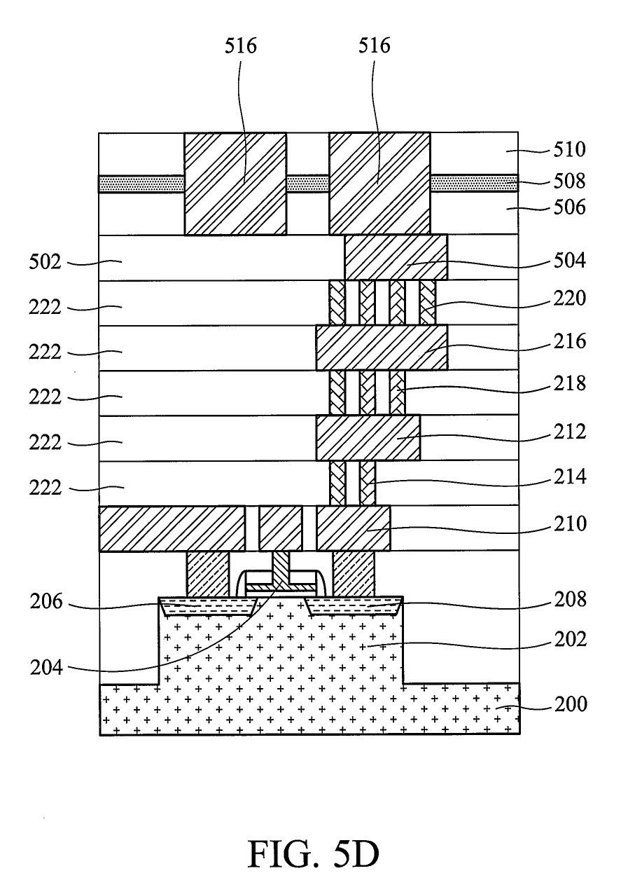

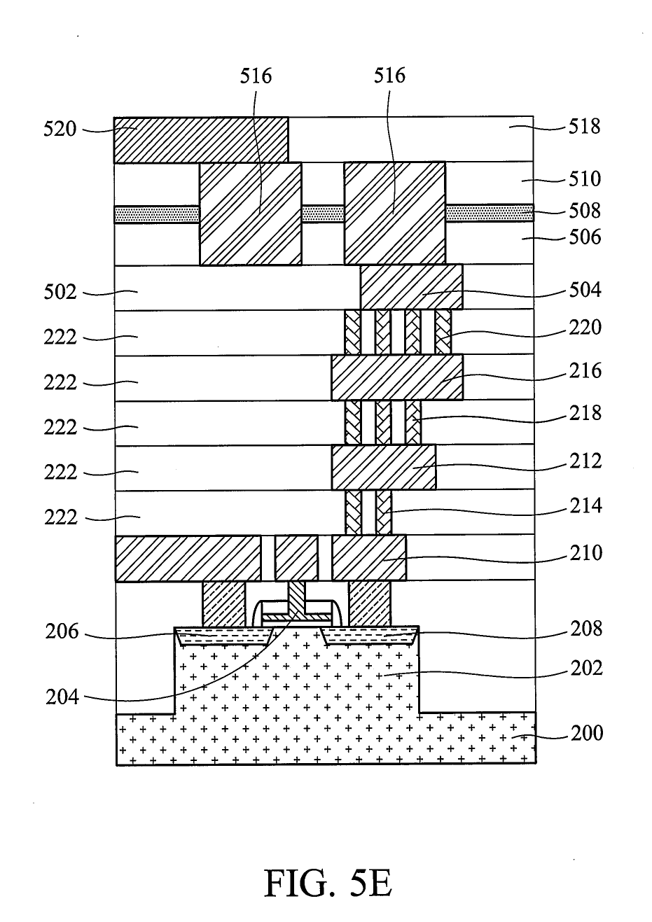

FIG. 5A˜FIG. 5E are intermediate cross sections of fabrication of a phase change memory device of another embodiment of the invention, wherein portions of the structure of the device of this embodiment under the bottom electrode are similar to the device of FIG. 2A˜FIG. 2E. Elements of this portions use the same symbol numbers as the device of FIG. 2A˜FIG. 2E. Referring to FIG. 5A, a substrate 200 comprising an active area 202 is provided, wherein a gate 204 is formed on the active area 202. Source 206 and drain 208, both doped regions, are formed on opposite sides of the gate 204. The gate 204, source 206 and drain 208 respectively connect to a first interconnect 210. A second interconnect 212 is connected to the first interconnect 210 through first vias 214. A third interconnect 216 is connected to the second interconnect 212 through second vias 218. A plurality of third vias 220 are formed on the third interconnect 216. The vias 214, 218 and 220 are disposed in interlayer dielectric layers 222 separating the interconnects 210, 212 and 216.

A first dielectric layer 502, comprising silicon nitride, silicon oxide or silicon oxynitride, is formed on the third vias 220 and patterned by a first photolithography step with a first mask to form an opening. Conductive materials, such as TiN, TaN or TiW, are deposited into the opening to form a bottom electrode 504.

Referring to FIG. 5B, a second dielectric layer 506, such as silicon nitride, silicon oxide or silicon oxynitride, is formed on the first dielectric layer 502 and the bottom electrode 504. Next, a phase change layer 508, comprising Ag, In, Te, Sb, Ge or combinations thereof, is blanlcetly deposited on the second dielectric layer 506, wherein the phase change layer 508 can be ternary chalcogenide compound, such as GeTe—Sb₂Te₃, or binary chalcogenide compound, such as a combination of Sb and Te of various percentages. The chalcogenide compound can comprise Cr, Fe, Ni or combinations thereof, or Bi, Pb, Sn, As, S, Si, P, O or combinations thereof. Thereafter, a third dielectric layer 510, such as silicon nitride, silicon oxide or silicon oxynitride, is formed on the phase change layer 508.

Referring to FIG. 5C, a photoresist layer 512 is coated on the third dielectric layer and defined by exposure with a third mask. Next, an etching process is utilized using the defined photoresist layer 512 as an etching mask to form at least two openings 514 in the second and third dielectric layers 506 and 510, the openings 514 penetrating the phase change layer 508, and the top electrode 504 or the first dielectric layer 502 are exposed.

Next, referring to FIG. 5D, refractory metals, such as W or TiAlN, metals with low heat conducting coefficient, phase change materials or Chalcogenide, are filled into the openings to form two columnar electrodes 516. Phase change layer 508 contacts both sidewalls of each columnar electrode 516.

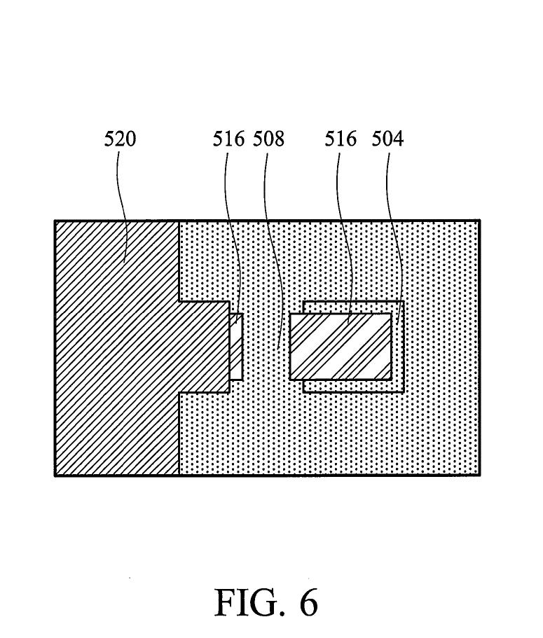

Referring to FIG. 5E, a fourth dielectric layer 518, such as silicon nitride, silicon oxide or silicon oxynitride, is formed on the columnar electrodes 516. Next, the fourth dielectric layer 518 is patterned by photolithography using a third mask to form an opening. A conductive material, such as TiN, TaN or TiW, is deposited into the opening, and then etched back to fonn a top electrode 520. FIG. 6 is a plan view of a phase change memory device of this embodiment. Referring to FIG. 6 and FIG. 5E, the entire phase change layer 508 is disposed on a plane, surrounding and contacting the columnar electrodes 516 in their entirety.

Note that fabrication of the phase change memory of this embodiment may use only three masks and photolithography steps, two mask and photolithography steps less than conventional planar phase change memory device.

In addition, the phase change memory device can be connected to a driving device, such as a MOSFET device, a BJT device or a diode.

According to the embodiments, since the patterned phase change layer is formed on a plane, the entirety of the patterned phase change layer can be planar, containing fewer defects and providing shorter current path than conventional phase change memory with phase change layer formed in/on a trench. In addition, area of a contact region between the phase change layer and the electrode can be determined by thickness of the phase change layer, not limited by a photolithography process. Further, fabrication of the phase change memory device of an embodiment of the invention requires fewer photolithography steps and/or masks than that of conventional phase change memory device.

While the invention has been described by way of example and in terms of the preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phase change memory device, comprising:
a first columnar electrode and a second columnar electrode , both arranged horizontally;
a phase change layer interposed between and electrically connecting the first columnar electrode and the second columnar electrode, wherein the entirety of the phase change layer is disposed on a plane;
a bottom electrode electrically connecting the first columnar electrode; and
a top electrode electrically connecting the second columnar electrode.

2. The phase change memory device as claimed in claim 1, wherein the phase change layer is patterned to form a patterned phase change layer.

3. The phase change memory device as claimed in claim 2, wherein patterning of the phase change layer extends into the first columnar electrode and the second columnar electrode.

4. The phase change memory device as claimed in claim 2, wherein patterning of the phase change layer only contacts sidewalls of the first columnar electrode and the second columnar electrode.

5. The phase change memory device as claimed in claim 1 further comprising a driving device connected to the phase change memory device.

6. The phase change memory device as claimed in claim 5, wherein the driving device comprises a MOSFET device, a BJT device and a diode.

7. The phase change memory device as claimed in claim 1, wherein the phase change layer comprises chalcogenide compound.

8. The phase change memory device as claimed in claim 7, wherein the chalcogenide compound is a ternary chalcogenide compound comprising Ge—Te—Sb.

9. The phase change memory device as claimed in claim 7, wherein the chalcogenide compound comprises Cr, Fe, Ni or combinations thereof, or the chalcogenide compound comprises Bi, Pb, Sn, As, S, Si, P, O or combinations thereof.

10. The phase change memory device as claimed in claim 1, wherein the first columnar electrode and the second columnar electrode comprise refractory metals, metals with low heat conducting coefficient or phase change materials.

11. The phase change memory device as claimed in claim 1, wherein the first columnar electrode and the second columnar electrode comprise W, TiAlN or chalcogenide compound.

12. The phase change memory device as claimed in claim 1, wherein the first columnar electrode and the second columnar electrode are at the same layer.

13. A method for forming a phase change memory device, comprising:
providing a substrate, comprising a source and a drain in MOS transistor;
forming a plurality of interconnects and vias, wherein at least one of the interconnects and vias electrically connects the source or the drain;
forming a bottom electrode and a first dielectric layer overlying the interconnects or the vias, wherein the bottom electrode is disposed in the first dielectric layer;
forming lower portions of a first columnar electrode and a second columnar electrode, and a second dielectric layer overlying the bottom electrode and the first dielectric layer, wherein the lower portions of the first columnar electrode and the second columnar electrode are disposed in the second dielectric layer, and the lower portion of the first columnar electrode electrically connects the bottom electrode;
forming a patterned phase change layer overlying portions of the lower portions of the first columnar electrode and the second columnar electrode, and the second dielectric layer;
forming upper portions of the first columnar electrode and the second columnar electrode, and a third dielectric layer overlying the lower portions of the first columnar electrode and the second columnar electrode, and a portion of the patterned phase change layer to form entireties of the first columnar electrode and the second columnar electrode, wherein the patterned phase change layer extends into the first columnar electrode and the second columnar electrode; and
forming a top electrode, electrically connecting a portion of the second columnar electrode.

14. The method for forming a phase change memory device as claimed in claim 13, wherein formation of a patterned phase change layer overlying portions of the lower portions of the first columnar electrode and the second columnar electrode, and the second dielectric layer comprises:
forming a phase change layer on the lower portions of the first columnar electrode and the second columnar electrode, and the second dielectric layer; and
patterning the phase change layer to form the patterned phase change layer, bridging the lower portions of the first columnar electrode and the second columnar electrode.

15. The method for forming a phase change memory device as claimed in claim 13, wherein formation of upper portions of the first columnar electrode and the second columnar electrode, and a third dielectric layer overlying lower portions of the first columnar electrode and the second columnar electrode, and a portion of the patterned phase change layer comprises:
forming a third dielectric layer on the lower portions of the first columnar electrode and the second columnar electrode, and the patterned phase change layer;
forming a patterned photoresist layer on the third dielectric layer;
etching the third dielectric layer using the patterned photoresist layer as a mask to form at least two openings, each respectively exposing the lower portion of the first columnar electrode and the lower portion of the second columnar electrode; and
depositing a conductive material in the openings to form an upper portion of the first columnar electrode and an upper portion of the second columnar electrode respectively on the lower portion of the first columnar electrode and the lower portion of the second columnar electrode, wherein the upper portion and the lower portion of the first columnar electrode constitute entirety of the first columnar electrode, and the upper portion and the lower portion of the second columnar electrode constitute entirety of the second columnar electrode.

16. The method for forming a phase change memory device as claimed in claim 15, wherein etching selectivity between the third dielectric layer and the patterned phase change layer is substantially more than 10 when etching the third dielectric layer.

17. The method for forming a phase change memory device as claimed in claim 13, wherein the phase change layer comprises chalcogenide compound.

18. The method for forming a phase change memory device as claimed in claim 17, wherein the chalcogenide compound is a ternary chalcogenide compound comprising Ge—Te—Sb.

19. The method for forming a phase change memory device as claimed in claim 17, wherein the chalcogenide compound comprises Cr, Fe, Ni or combinations thereof, or the chalcogenide compound comprises Bi, Pb, Sn, As, S, Si, P, O or combinations thereof.

20. The method for forming a phase change memory device as claimed in claim 13, wherein the first columnar electrode and the second columnar electrode comprise refractory metals or metals with low heat conducting coefficient.

21. The method for forming a phase change memory device as claimed in claim 13, wherein the first columnar electrode and the second columnar electrode comprise W or TiAlN.

22. A method for forming a phase change memory device, comprising:
providing a substrate, comprising a source and a drain in MOS transistor;
forming a plurality of interconnects and vias, wherein at least one of the interconnects and vias electrically connects the source or the drain;
forming a bottom electrode and a first dielectric layer overlying the interconnects or the vias, wherein the bottom electrode is disposed in the first dielectric layer;
forming a second dielectric layer overlying the bottom electrode and the first dielectric layer;
forming a phase change layer overlying the second dielectric layer;
forming a third dielectric layer overlying the phase change layer and the second dielectric layer;
forming a patterned photoresist layer overlying the third dielectric layer;
etching the second dielectric layer and the third dielectric layer using the patterned photoresist layer as a mask to form at least two openings, wherein the openings penetrate portions of the phase change layer; and
filling a conductive material into the openings to form at least two columnar electrodes.

23. The method for forming a phase change memory device as claimed in claim 22, further comprising patterning the phase change layer to form a patterned phase change layer, wherein the openings penetrates a portion of the patterned phase change layer.

24. The method for forming a phase change memory device as claimed in claim 23, wherein the patterned phase change layer connects sidewalls of the columnar electrodes.

25. The method for forming a phase change memory device as claimed in claim 22, further comprising a top electrode, electrically connecting one of the columnar electrodes.

26. The method for forming a phase change memory device as claimed in claim 22, wherein the phase change layer connects sidewalls of the columnar electrodes.

27. The method for forming a phase change memory device as claimed in claim 22, wherein the phase change layer comprises chalcogenide compound.

28. The method for forming a phase change memory device as claimed in claim 27, wherein the chalcogenide compound is ternary chalcogenide compound, comprising Ge—Te—Sb.

29. The method for forming a phase change memory device as claimed in claim 28, wherein the chalcogenide compound comprises Cr, Fe, Ni or combinations thereof, or the chalcogenide compound comprises Bi, Pb, Sn, As, S, Si, P, O or combinations thereof.

30. The method for forming a phase change memory device as claimed in claim 22, wherein the first columnar electrode and the second columnar electrode comprise refractory metals, metals with low heat conducting coefficient or phase change materials.

31. The method for forming a phase change memory device as claimed in claim 22, wherein the first columnar electrode and the second columnar electrode comprise W, TiAIN or chalcogenide compound.
